(19) United States
(12) Patent Application Publication
(10) Pub. No.: US 2025/0054815 A1
(43) Pub. Date: Feb. 13, 2025

(54) MANUFACTURING METHOD OF SUBSTRATE WITH PROTECTIVE MEMBER

(71) Applicant: DISCO CORPORATION, Tokyo (JP)

(72) Inventors: Mitsuru IKUSHIMA, Tokyo (JP); Yoshikuni MIGIYAMA, Tokyo (JP); Yoshinori KAKINUMA, Tokyo (JP); Yuta TANIYAMA, Tokyo (JP)

(21) Appl. No.: 18/786,841

(22) Filed: Jul. 29, 2024

(30) Foreign Application Priority Data
Aug. 10, 2023 (JP) 2023-131476

(51) Int. Cl. H01L 21/66; H01L 21/56

(52) U.S. Cl. CPC H01L 22/12; H01L 21/56

(57) ABSTRACT

There is provided a manufacturing method of a substrate with a protective member in which a protective member of a size corresponding to a substrate is provided on one side of the substrate, the method including a protective member forming step, a removing step of, after the protective member forming step, causing a cutter to cut into the protective member along a peripheral edge of the substrate and separating the protective member into a surplus portion extending beyond the peripheral edge of the substrate and a main body portion of the protective member on an inner side than the peripheral edge of the substrate, to remove the surplus portion, and a determining step of, after the removing step, observing the peripheral edge of the main body portion and determining presence or absence of occurrence of an abnormality at the peripheral edge of the main body portion.

### BACKGROUND OF THE INVENTION

### Field of the Invention

The present invention relates to a manufacturing method of a substrate with a protective member.

### Description of the Related Art

Wafers in which a plurality of devices, as typified by integrated circuits (ICs), are formed on a face side thereof are processed by being ground on a reverse side thereof by a grinding apparatus to a predetermined thickness. The wafers processed to a predetermined thickness are each cut according to the size of each device by a dicing apparatus, for example, and divided into a plurality of device chips corresponding to the respective devices. The device chips obtained in such a manner are thereafter incorporated in electronic equipment, for example.

In order to absorb the shock applied to the face side of the wafer when the wafer is ground as described above, a protective member is formed on the face side of the wafer. For example, Japanese Patent Laid-open No. 2021-27239 describes a protective member forming method of forming a protective member on a face side of a substrate which has, on the face side, irregularities such as device patterns and bumps.

In the protective member forming method described in Japanese Patent Laid-open No. 2021-27239, first, a resin film containing no glue layer is adhered to the face side of the substrate, and then, liquid resin is supplied to a face side of the resin film. Thereafter, a cover film is disposed on the liquid resin, and pressed downward. As a result, the liquid resin spreads over the face side of the resin film. Thereafter, the liquid resin is cured, and a protective member is completed.

Further, Japanese Patent Laid-open No. 2022-162633 describes a method of removing a surplus portion of a protective member that extends beyond a peripheral edge of the substrate, when a protective member greater in width than the substrate is formed on the substrate. In the method disclosed in Japanese Patent Laid-open No. 2022-162633, a cutter is caused to cut into the protective member along the peripheral edge of the substrate such that the protective member is separated into a surplus portion that extends beyond the peripheral edge of the substrate and a main body portion on the inner side than the peripheral edge of the substrate.

### SUMMARY OF THE INVENTION

When the protective member is cut by the method of causing the cutter to cut into the protective member as described in Japanese Patent Laid-open No. 2022-162633 described above, the protective member may partially be peeled off from the substrate, or burrs may be generated from the protective member in some cases. In particular, when the protective member is configured by a plurality of layers, compared to a case in which the protective member is configured by a single layer, the probability of occurrence of such an abnormality in quality as described above increases. Further, using the protective member in which an abnormality in quality has occurred as it is reduces the quality of the final product.

It is therefore an object of the present invention to provide a manufacturing method of a substrate with a protective member that is capable of determining presence or absence of an abnormality in quality of a protective member formed on a substrate.

In accordance with an aspect of the present invention, there is provided a manufacturing method of a substrate with a protective member in which a protective member of a size corresponding to a substrate is provided on one side of the substrate, the method including a protective member forming step of forming a protective member having a width greater than a width of the substrate, on the one side of the substrate, a removing step of, after the protective member forming step, causing a cutter to cut into the protective member along a peripheral edge of the substrate and separating the protective member into a surplus portion extending beyond the peripheral edge of the substrate and a main body portion on an inner side than the peripheral edge of the substrate, to remove the surplus region, and a determining step of, after the removing step, observing a peripheral edge of the main body portion and determining presence or absence of occurrence of an abnormality at the peripheral edge of the main body portion.

Preferably, the manufacturing method of a substrate with a protective member further includes a reference image acquiring step of, after the protective member forming step but before the removing step, imaging the protective member at a portion corresponding to the peripheral edge of the substrate and acquiring a reference image that serves as reference for determination in the determining step, and a determination target image acquiring step of, after the removing step but before the determining step, imaging the peripheral edge of the main body portion of the protective member and acquiring a determination target image that would be used for determination in the determining step, and, in the determining step, the reference image and the determination target image are compared.

Preferably, in the determining step, a difference between luminance of each of a plurality of pixels constituting the determination target image and luminance of each of a plurality of pixels constituting the reference image is taken to form a difference image that includes a first region including pixels of low luminance and a second region including pixels of higher luminance than the pixels constituting the first region, and, when a size of the second region indicated in the difference image exceeds a threshold, an abnormality is determined to have occurred.

Preferably, the manufacturing method further includes a pressing step of, after the removing step but before the determining step, pressing the peripheral edge of the main body portion by a roller.

Preferably, the manufacturing method further includes a pressing step of, after the determining step, pressing the peripheral edge of the main body portion by a roller.

Preferably, the manufacturing method further includes a peeling-off step of peeling off the main body portion from the substrate when, in the determining step, an abnormality is determined to have occurred, and, after the peeling-off step, the protective member forming step, the removing step, and the determining step that use the protective member newly formed are carried out.

Preferably, the protective member forming step includes a resin film adhering step of causing one side of a resin film having a width greater than the width of the substrate to adhere to the one side of the substrate, a liquid resin supplying step of supplying liquid resin to a side of the resin film opposite to the one side thereof, and a cover film disposing step of disposing a cover film having a width greater than the width of the substrate on the resin and curing the resin.

In the manufacturing method of a substrate with a protective member according to an aspect of the present invention, a cutter is caused to cut into the protective member along the peripheral edge of the substrate, so that the protective member is separated into a surplus region that extends beyond the peripheral edge of the substrate and a main body portion that is on the inner side than the peripheral edge of the substrate. Thereafter, the peripheral edge of the main body portion is observed, and the presence or absence of an abnormality in quality at the peripheral edge of the main body portion is determined. Thus, the presence or absence of an abnormality in quality of the protective member formed on the substrate can be determined.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a substrate;

FIG. 2 is a cross sectional view of the substrate;

FIG. 3 is a cross sectional view of a substrate with a protective member;

FIG. 4 is a flowchart of a manufacturing method of the substrate with the protective member;

FIG. 5 is a flowchart in which a protective member forming step according to a first embodiment of the present invention is further subdivided;

FIG. 6 is a cross sectional view illustrating the substrate, a resin film, and other members at the time when a resin film adhering step is carried out;

FIG. 7 is a cross sectional view illustrating the substrate, the resin film, the liquid resin, and other members at the time when a resin supplying step is carried out;

FIG. 8 is a cross sectional view illustrating the substrate, the resin film, the liquid resin, a cover film, and other members at the time when a cover film disposing step is carried out;

FIG. 9 is a cross sectional view illustrating the substrate, the protective member, and other members at the time when a reference image acquiring step is carried out;

FIG. 10 is a top view of a support member;

FIG. 11 illustrates an example of an image acquired in the reference image acquiring step;

FIG. 12 is a cross sectional view illustrating the substrate, the protective member, and other members at the time when a removing step is carried out;

FIG. 13 illustrates an example of an image acquired in a determination target image acquiring step;

FIG. 14 depicts an image indicating a difference between the image acquired in the reference image acquiring step and the image acquired in the determination target image acquiring step;

FIG. 15 is an enlarged view of a portion “A” illustrated in FIG. 14;

FIG. 16 is an enlarged view of a portion “B” illustrated in FIG. 14; and

FIG. 17 is a flowchart of the protective member forming step according to a second embodiment of the present invention.

### DETAILED DESCRIPTION OF THE PREFERRED EMBODIMENTS

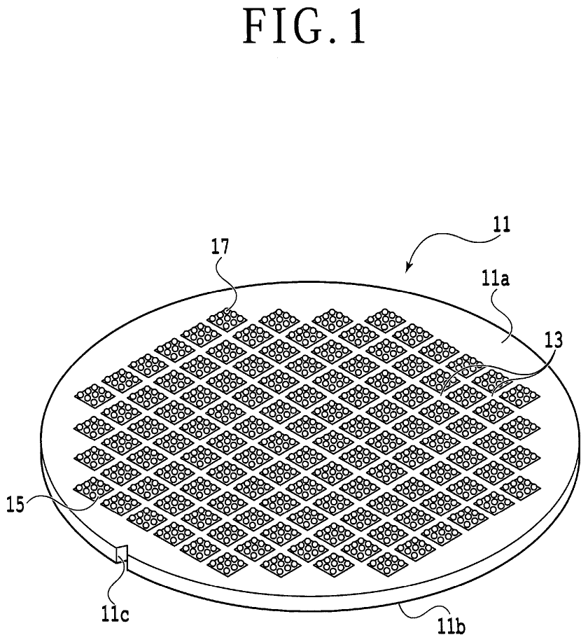

Embodiments of the present invention will be described below with reference to the attached drawings. First, a substrate to be used in a manufacturing method of a substrate with a protective member according to a first embodiment of the present invention will be described. FIG. 1 is a perspective view of the substrate denoted by 11. The substrate 11 according to the first embodiment is, for example, a disk-shaped wafer configured by a semiconductor material such as silicon. Specifically, as illustrated in FIG. 1, the substrate 11 is configured to have a substantially disk shape and includes a substantially circular face side 11a and a substantially circular reverse side 11b on an opposite side of the face side 11a. At a portion of a peripheral edge of the substrate 11, a notch 11c for indicating the crystal orientation of the substrate 11 is formed.

The substrate 11 has a diameter (width of the face side 11a or the reverse side 11b) of, for example, 100 to 450 mm, typically, 300 mm. The substrate 11 has a thickness of, for example, 0.1 to 1.0 mm, typically, 0.775 mm. Note that the material, the shape, the diameter (width of the face side 11a or the reverse side 11b), and the thickness of the substrate 11 are not limited to the examples described above. Further, the substrate 11 may be provided with an orientation flat in place of the notch 11c. Further, the substrate 11 may not be provided with the notch 11c or an orientation flat.

A plurality of linear streets 13 each having a predetermined width are set in a grid pattern on the face side 11a of the substrate 11. These streets 13 are used to partition the face side 11a of the substrate 11 into a plurality of areas, each of which is provided with a device 15 as exemplified by an IC.

Substantially sphere-shaped bumps (protrusions) 17 formed of a metal material such as gold, silver, copper, or aluminum, for example, are formed on a face side of the device 15. The bumps 17 are formed on the face side of the device 15 by solder balls being bonded or electroplating being applied. The bumps 17 each have a diameter of, for example, 5 to 100 μm, typically, 20 μm. The bumps 17 are electrically connected to the devices 15 and function as electrodes (terminals) when electric signals are input/output to/from the devices 15. Yet, the bumps 17 are not limited to having such shapes and sizes or being formed of such materials.

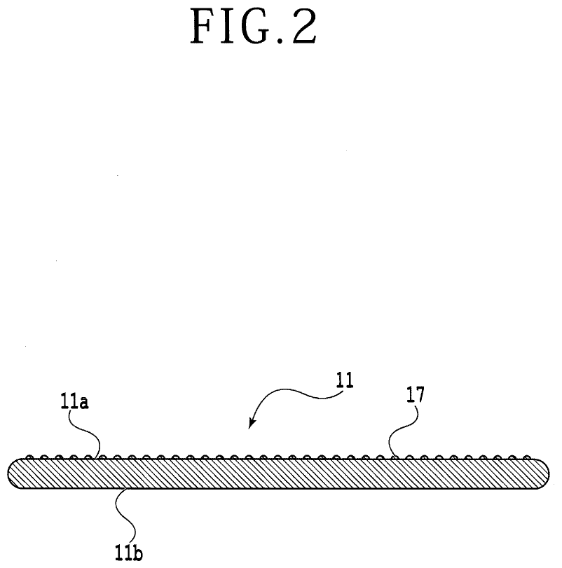

FIG. 2 is a cross sectional view of the substrate. As illustrated in FIG. 2, the bumps 17 are formed on the face sides of the devices 15, generating a recessed/protruding structure on the face side 11a of the substrate 11. Specifically, the size of the step between the recessed portion and the protruding portion that configure the recessed/protruding structure corresponds to the size of the diameter of each bump 17. Yet, the bumps 17 may not be formed on the face side 11a of the substrate 11.

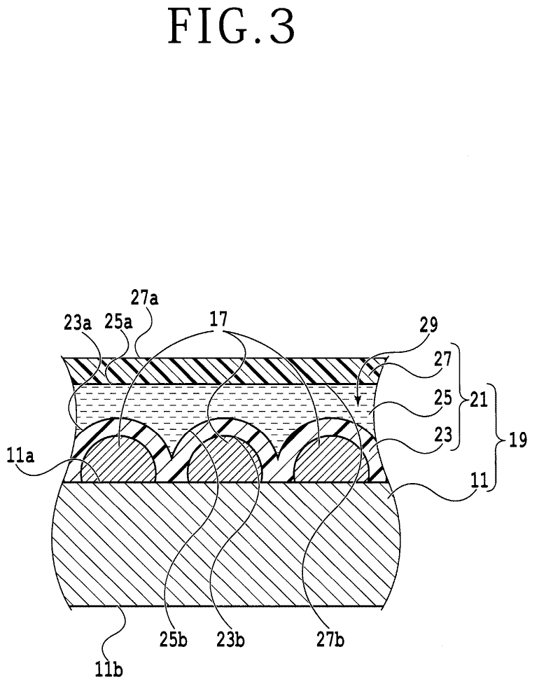

FIG. 3 is a cross sectional view of a substrate 19 with a protective member manufactured by the manufacturing method of a substrate with a protective member according to the first embodiment. As illustrated in FIG. 3, a protective member 21 is provided on the face side 11a of the substrate 11 in such a manner as to cover the face side 11a of the substrate 11. The protective member 21 is disposed on the face side 11a of the substrate 11 and is configured to have a disk shape of a diameter substantially the same as that of the substrate 11.

The protective member 21 has a disk-shaped resin film 23 that has substantially the same diameter as the substrate 11. Specifically, the resin film 23 includes one side (second side) 23b that comes into contact with the face side 11a of the substrate 11 and that has a substantially circular shape and another side (first side) 23a that is on the opposite side of the one side 23b.

The resin film 23 is configured with a material that is, for example, a high polymer material such as polyolefin and polyethylene. The resin film 23 may be one in which two or more layers configured from any kind of resin selected from these materials are laminated. The resin film 23 has a thickness of, for example, 80 to 250 μm, typically, 150 μm. Yet, the resin film 23 is not limited to having such a thickness or being formed of such materials.

The thickness of the resin film 23 is sufficiently smaller than the diameter of the bump 17 described above. The one side 23b of the resin film 23 is adhered to the face side 11a of the substrate 11. Thus, on the other side 23a of the resin film 23, a recessed/protruding structure 29 reflecting the recessed/protruding structure of the bumps 17 formed on the face side 11a of the substrate 11 is generated.

A resin layer 25 is provided on the other side 23a of the resin film 23. The resin layer 25 is so formed as to cover the other side 23a of the resin film 23 and is configured to have a disk-shape of a diameter substantially equal to that of the resin film 23. Specifically, the resin layer 25 has one side (second side) 25b that comes into contact with the other side 23a of the resin film 23 and that has a substantially circular shape and another side (first side) 25a that is on the opposite side of the one side 25b.

The resin layer 25 is a cured product of ultraviolet curable resin. Examples of the ultraviolet curable resin includes epoxy resin and acrylic resin. The resin layer 25 has a thickness of, for example, 80 to 400 μm, typically, 200 μm. Yet, the resin layer 25 is not limited to having such a thickness or being formed of such materials.

The thickness of the resin layer 25 is sufficiently larger than the size of the step between the recessed portion and the protruding portion on the other side 23a of the resin film 23 (that is, the size of the recessed/protruding structure 29). The recessed/protruding structure 29 of the resin film 23 is completely embedded and absorbed in the one side 25b of the resin layer 25. Thus, the other side (first side) 25a of the resin layer 25 is substantially flat.

A cover film 27 configured to have a disk-shape of substantially the same diameter as the resin layer 25 is so provided on the other side 25a of the resin layer 25 as to cover the other side 25a of the resin layer 25. The cover film 27 has one side (second side) 27b that comes into contact with the other side 25a of the resin layer 25 and that has a substantially circular shape and another side (first side) 27a on the opposite side of the one side 27b. The other side 27a of the cover film 27 is exposed to the outside as the face side of the protective member 21.

The cover film 27 is formed with a material and a thickness that allow ultraviolet rays for curing the ultraviolet curable resin constituting the resin layer 25 to transmit therethrough. For example, the cover film 27 has a thickness of, for example, 80 to 150 μm, typically, 80 μm. Such a thickness allows ultraviolet rays to appropriately transmit through the cover film 27 and cure the resin layer 25. Yet, the thickness of the cover film 27 is not limited to such a thickness.

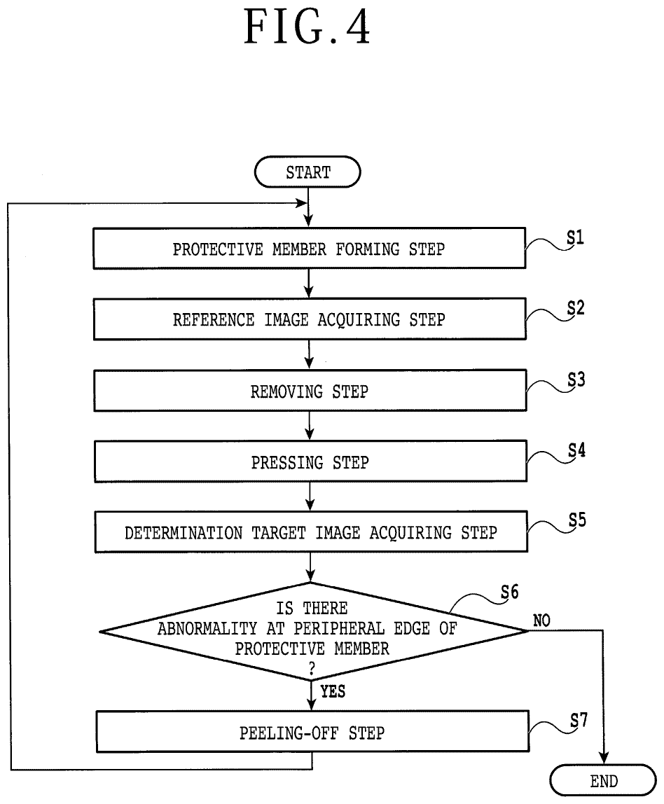

Next, a description will be given of the manufacturing method of a substrate with a protective member that is used for manufacturing the substrate 19 with the protective member described above. FIG. 4 is a flowchart illustrating the manufacturing method of a substrate with a protective member according to the first embodiment. As illustrated in FIG. 4, the manufacturing method of a substrate with a protective member according to the first embodiment includes a protective member forming step S1, a reference image acquiring step S2, a removing step S3, a pressing step S4, a determination target image acquiring step S5, a determining step S6, and a peeling-off step S7.

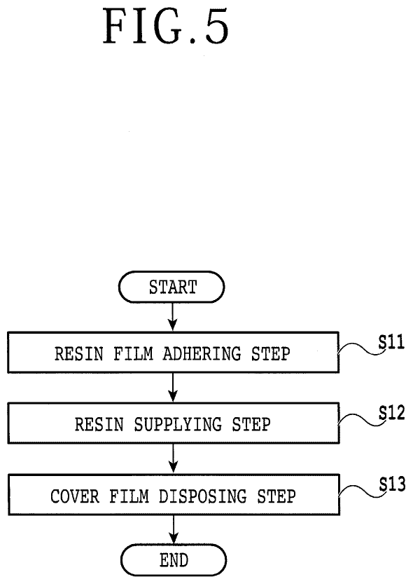

In the protective member forming step S1, the protective member 21 is formed on the substrate 11. FIG. 5 is a flowchart in which the protective member forming step S1 is further subdivided. As illustrated in FIG. 5, the protective member forming step S1 includes a resin film adhering step S11, a resin supplying step S12, and a cover film disposing step S13.

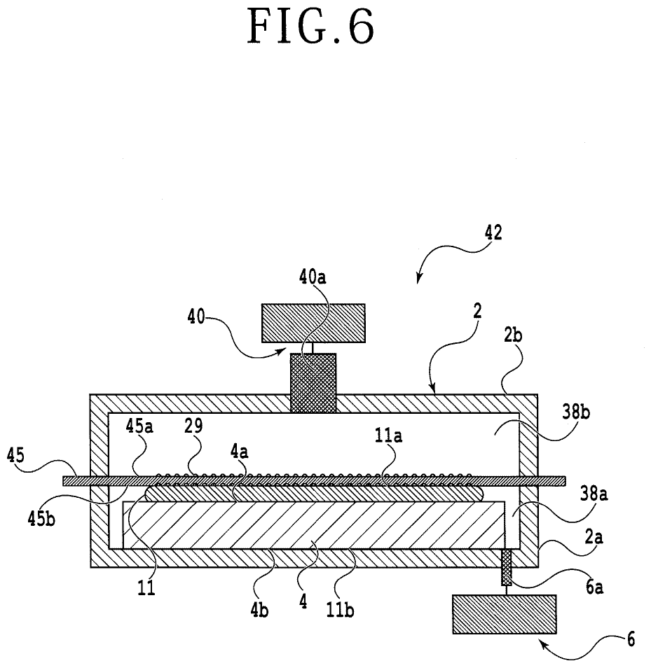

FIG. 6 is a cross sectional view illustrating the substrate 11, a resin film 45, and other members at the time when the resin film adhering step S11 is carried out. In the resin film adhering step S11, a resin film adhering apparatus 42 illustrated in FIG. 6 is used. The resin film adhering apparatus 42 includes a vacuum chamber 2. The vacuum chamber 2 includes a lower chamber 2a that has a recessed portion open upward and an upper chamber 2b that is arranged above the lower chamber 2a and that has a recessed portion open downward. The lower chamber 2a is connected to a negative-pressure source 6. The upper chamber 2b is connected to a negative-pressure source 40.

An opening portion on an upper end of the lower chamber 2a and an opening portion on a lower end of the upper chamber 2b have substantially the same shape. Hence, when the upper chamber 2b is placed on top of the lower chamber 2a such that the opening portions thereof are overlapped, a hermetically sealed space isolated from the outside is formed inside the upper chamber 2b and the lower chamber 2a. Note that each of the opening portions is larger than the substrate 11 to allow the substrate 11 to be housed inside the hermetically sealed space.

A support table 4 for supporting the substrate 11 is provided in the recessed portion of the lower chamber 2a. The support table 4 is configured to have a substantially disk-shape and includes a substantially circular face side 4a and a substantially circular reverse side 4b. The face side 4a of the support table 4 has a diameter (width) slightly larger than that of the substrate 11 to come into contact with the entire reverse side 11b of the substrate 11 and hold the substrate 11. For example, the diameter (width) of the face side 4a is larger than the diameter (width) of the substrate 11 by 0.2 mm or more but 20 mm or less, typically, by 1 mm.

For example, a height of the support table 4 is so adjusted that, when the substrate 11 is placed on the face side 4a, the face side 11a of the substrate 11 and the opening portion of the lower chamber 2a become substantially identical in height. Alternatively, the height of the support table 4 is so adjusted that the opening portion of the lower chamber 2a becomes higher than the face side 11a of the substrate 11. In this case, when the resin film 45 is placed on the support table 4 to adhere to the substrate 11 as described below, the resin film 45 is unlikely to adhere to the side surface of the substrate 11 over an unnecessarily wide range.

Note that the support table 4 may have such a configuration that the substrate 11 can be sucked and held. Specifically, the support table 4 may have a through hole which has one end open on the face side 4a of the support table 4 and another end connected to a negative-pressure source (not illustrated). Causing the negative pressure from the negative-pressure source to act on the face side 4a of the support table 4 via the through hole in a state in which the substrate 11 is in contact with the face side 4a of the support table 4 allows the substrate 11 to be sucked and held on the face side 4a of the support table 4.

One end of an exhaust channel 6a is connected to a bottom wall of the lower chamber 2a. To the other end of the exhaust channel 6a, the negative-pressure source 6 is connected. That is, the lower chamber 2a is connected to the negative-pressure source 6 via the exhaust channel 6a. Further, one end of an exhaust channel 40a is connected to a ceiling of the upper chamber 2b. To the other end of the exhaust channel 40a, the negative-pressure source 40 is connected. That is, the upper chamber 2b is connected to the negative-pressure source 40 via the exhaust channel 40a.

In the resin film adhering step S11, first, the substrate 11 is disposed on the support table 4 such that the reverse side 11b of the substrate 11 faces the face side 4a of the support table 4 in a state in which the upper chamber 2b has not yet been place on top of the lower chamber 2a. Next, the resin film 45 that subsequently becomes the resin film 23 is disposed on the face side 11a of the substrate 11.

As the resin film 45, one that has a width (or diameter) greater than that of the opening portion of the lower chamber 2a is used to allow a space 38a that is closed by the lower chamber 2a and the resin film 45 to be formed when the resin film 45 is disposed on the face side 11a of the substrate 11. That is, the resin film 45 has a size that extends beyond a peripheral edge of the opening portion of the lower chamber 2a. Specifically, the width (or diameter) of the resin film 45 is greater than the width (width of the opening portion) of the lower chamber 2a by 10 mm or more but 150 mm or less, typically, by 60 mm.

Thereafter, the upper chamber 2b is placed above the lower chamber 2a with the resin film 45 interposed therebetween. As a result, an upper portion of the lower chamber 2a is adhered to a second surface (lower surface) 45b of the resin film 45, and a space 38a closed by the lower chamber 2a and the resin film 45 is formed. Further, a lower portion of the upper chamber 2b is adhered to a first surface (upper surface) 45a of the resin film 45, and a space 38b closed by the upper chamber 2b and the resin film 45 is formed.

As described above, when the resin film 45 is disposed on the face side 11a of the substrate 11, the inside of the vacuum chamber 2 is separated into the upper space 38b and the lower space 38a by the resin film 45. Further, when the negative-pressure source 40 is operated together with the negative-pressure source 6, air inside each of the space 38a and the space 38b is exhausted, and the space 38a and the space 38b are depressurized. The degree of vacuum (atmospheric pressure) inside the vacuum chamber 2 is, for example, as in the space 38a and the space 38b, not more than 1000 Pa, typically, 100 Pa. Thereafter, only the negative-pressure source 40 that depressurizes the space 38b is stopped, and the space 38b is opened to air.

As a result, a great pressure difference is momentarily generated between the space 38a and the space 38b separated by the resin film 45. This pressure difference applies a force that acts toward the substrate 11 to the resin film 45, which in turn adheres to the face side 11a of the substrate 11 in such a manner as to follow the irregularities on the face side 11a of the substrate 11. As described above, using the vacuum chamber 2 makes it possible to cause the resin film 45 to adhere to the face side 11a of the substrate 11. After the resin film 45 has been adhered to the substrate 11, the negative-pressure source 6 is stopped, and the space 38a is opened to air.

Further, for example, when the upper chamber 2b is lifted and the lower chamber 2a and the upper chamber 2b are separated from each other, the substrate 11 and the resin film 45 adhered to the substrate 11 are conveyed from the support table 4. Thereafter, the portion of the resin film 45 extending beyond the peripheral edge of the substrate 11 is cut off. However, the resin film 45 is cut in a size sufficiently larger than the substrate 11, such that the liquid resin supplied in the next resin supplying step S12 does not stick to the substrate 11.

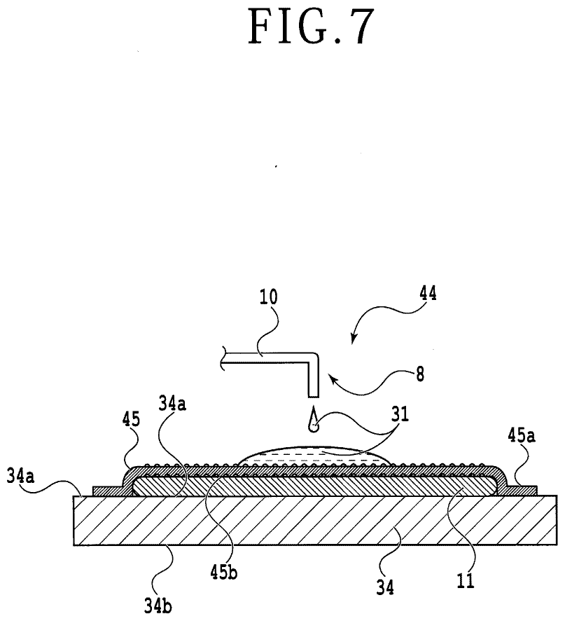

FIG. 7 is a cross sectional view illustrating the substrate 11, the resin film 45, the liquid resin 31, and other members at the time when the resin supplying step S12 is carried out. In the resin supplying step S12, a resin layer forming apparatus 44 illustrated in FIG. 7 is used. The resin layer forming apparatus 44 includes a support table 34. A resin supply unit 8 for supplying the liquid resin 31 to the first surface 45a of the resin film 45 is disposed near the support table 34.

The resin supply unit 8 has a shaft (not illustrated) extending along a vertical direction, an arm (not illustrated) that is provided on an upper end portion of the shaft and extending in a horizontal direction, and a nozzle 10 that is provided on a distal end portion of the arm and oriented downward. The shaft is configured to be rotatable about a rotational axis (not illustrated) extending along the vertical direction.

The resin supply unit 8 is connected to one end of a resin supply pipe (not illustrated). The other end of the resin supply pipe is connected to a tank (not illustrated) that reserves resin. When a valve or the like provided in the resin supply pipe is opened, the liquid resin 31 flows toward the nozzle 10 from the tank via the resin supply pipe and drops downward from the nozzle 10.

In the resin supplying step S12, first, the substrate 11 to which the resin film 45 is adhered is conveyed to the support table 34. Next, the shaft of the resin supply unit 8 is rotated, and the position of the nozzle 10 is adjusted. Specifically, the nozzle 10 is positioned above the substrate 11 disposed on the support table 34. Thereafter, the liquid resin 31 is supplied from the nozzle 10 of the resin supply unit 8 to the first surface 45a of the resin film 45.

The liquid resin 31 is ultraviolet curable resin that constitutes the resin layer 25 and that has not yet been cured, and has predetermined fluidity. The amount of the liquid resin 31 to be supplied to the first surface 45a of the resin film 45 is adjusted according to the thickness of the resin layer 25 to be formed after the liquid resin 31 is cured. That is, the liquid resin 31 in such an amount that the cured resin layer 25 has a thickness of 80 to 400 μm is supplied to the first surface 45a.

After the supply of resin to the substrate 11 from the resin supply unit 8 is ended, the shaft of the resin supply unit 8 is rotated again, so that the nozzle 10 is moved (evacuated) from the upper side of the support table 34.

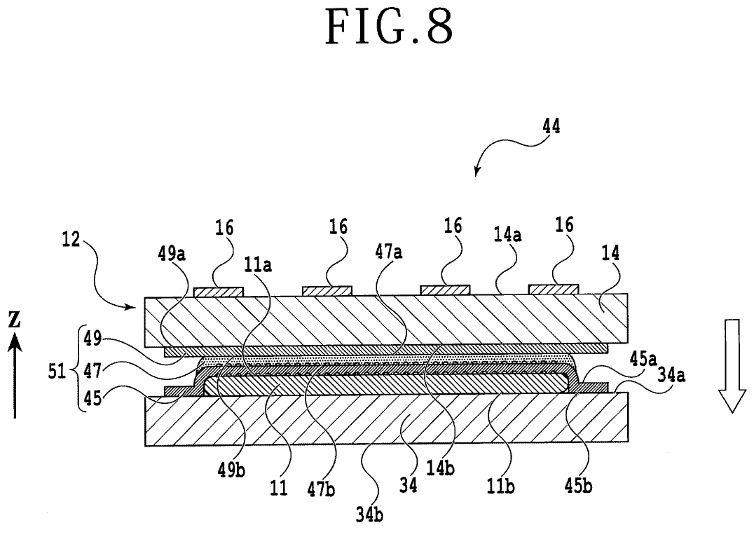

FIG. 8 is a cross sectional view illustrating the substrate 11, the resin film 45, the liquid resin 31, a cover film 49, and other members at the time when the cover film disposing step S13 is carried out. In the cover film disposing step S13, the resin layer forming apparatus 44 is continuously used. As illustrated in FIG. 8, the resin layer forming apparatus 44 has a pressing unit 12 disposed above the support table 34. The pressing unit 12 includes a pressing member 14.

The pressing member 14 is a substantially disk-shaped member including a substantially circular first surface 14a and a substantially circular flat second surface (pressing surface) 14b. The pressing member 14 is configured with a material and a thickness that allow ultraviolet rays to transmit therethrough. For example, on the second surface 14b, one end of a suction hole (not illustrated) provided in the pressing member 14 is open. The other end of the suction hole is connected to a negative-pressure source. That is, a negative pressure from the negative-pressure source acts on the second surface 14b via the suction hole.

Light sources 16 are provided on the first surface 14a of the pressing member 14. Each of the light sources 16 emits light (ultraviolet rays) having a wavelength that can cure the ultraviolet curable liquid resin 31. The light sources 16 each emit light of a wavelength of, for example, 200 to 400 nm, typically, 365 nm. Note that the pressing member 14 allows the light emitted from the light sources 16 to transmit therethrough, as described above.

In the cover film disposing step S13, first, the negative-pressure source causes a negative pressure to act on the second surface 14b in a state in which the second surface 14b is in contact with the cover film 49. As a result, the cover film 49 is held by the pressing member 14.

The cover film 49 is configured to have a disk-shape and includes a substantially circular first surface 49a and a substantially circular second surface 49b. The cover film 49 has a diameter (width) slightly larger than that of the substrate 11. Specifically, the cover film 49 has a diameter (width) larger than the diameter (width) of the substrate 11 by 30 mm or more but 200 mm or less, typically, by 100 mm.

Next, the pressing unit 12 lowers the pressing member 14 in a state in which the cover film 49 is held by the second surface 14b. As a result, the liquid resin 31 is pressed from the upper side by the second surface 14b via the cover film 49 and is spread out. Further, the pressing unit 12 causes the light sources 16 to emit ultraviolet rays, and the ultraviolet rays emitted from the light sources 16 cure the liquid resin 31. When the liquid resin 31 is completely cured and a resin layer 47 is formed, the pressing unit 12 causes the light sources 16 to stop emitting ultraviolet rays.

Thereafter, the pressing unit 12 stops the negative-pressure source connected to the suction hole provided in the pressing member 14. As a result, holding of the cover film 49 by the second surface 14b of the pressing member 14 is cancelled. When the pressing unit 12 is lifted in this state, the cover film 49 is left on the resin layer 47 formed by the cured liquid resin 31. That is, a protective member 51 in which the resin film 45, the resin layer 47, and the cover film 49 are integrated is formed on the face side 11a of the substrate 11. This completes the series of steps included in the protective member forming step S1.

After the protective member forming step S1, the reference image acquiring step S2 and the removing step S3 are carried out. In the reference image acquiring step 2, the substrate 11 and the protective member 51 are imaged from an upper side by a camera. Further, in the removing step S3, a portion of the protective member 51 extending beyond the peripheral edge of the substrate 11 is cut by a cutter. As a result, the substrate 19 with the protective member in which the substrate 11 and the protective member 21 are integrated and which is illustrated in FIG. 3 is formed.

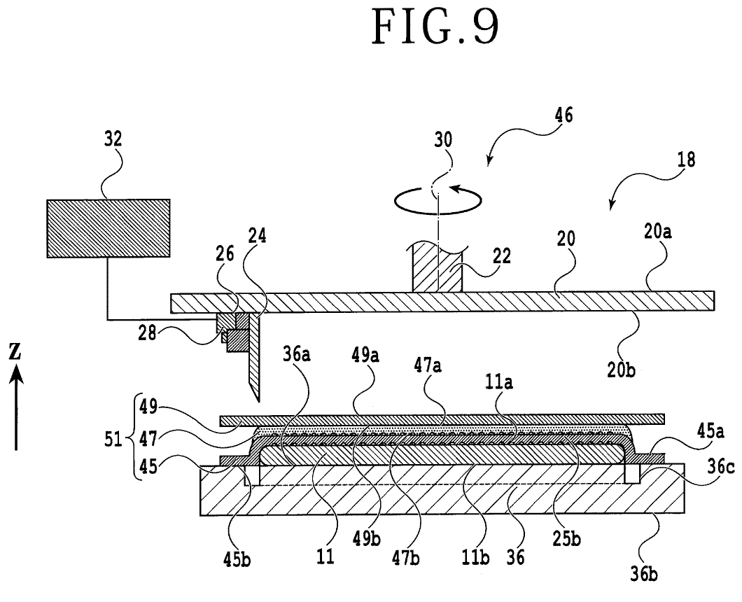

FIG. 9 is a cross sectional view illustrating the substrate 11, the protective member 51, and other members at the time when the reference image acquiring step S2 is carried out. In the reference image acquiring step S2, a cutting apparatus 46 illustrated in FIG. 9 is used. The cutting apparatus 46 includes a cutting unit 18.

The cutting unit 18 includes a spindle 22. One end portion (base end portion) of the spindle 22 is connected to a rotary drive source (not illustrated) such as a motor. By power from this rotary drive source, the spindle 22 rotates about a rotational axis 30 passing through the axis thereof. Further, the spindle 22 is supported by a Z-axis moving mechanism (not illustrated), together with the rotary drive source. Hence, when the Z-axis moving mechanism is operated, the spindle 22 moves up and down along a Z-axis.

A support member 20 is fixed to the other end portion (distal end portion) of the spindle 22. The support member 20 is configured to have a substantially disk shape and includes a substantially circular first surface 20a and a substantially circular second surface 20b. The distal end portion of the spindle 22 is fixed to the first surface 20a side of the support member 20.

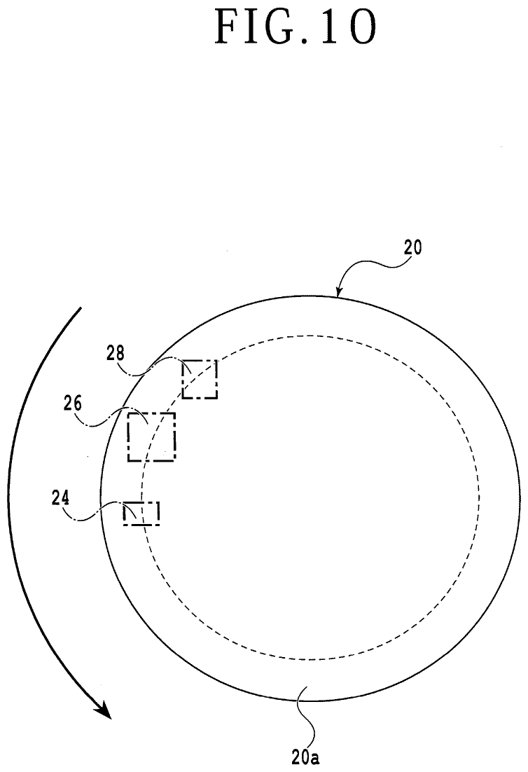

On the second surface 20b side, a cutter 24 used for cutting the protective member 51, a roller 26 for pressing, and a camera 28 for imaging a lower region are fixed in such a manner that each of their positions can be finely adjusted. As illustrated in FIG. 10, the cutter 24 including a cutting blade, the roller 26, and the camera 28 are arranged along a circumference of one same circle which has the center of the second surface 20b as its center and a diameter smaller than the diameter of the second surface 20b, in the second surface 20b of the support member 20. Note that this circle has, for example, substantially the same diameter as the substrate 11.

Further, the cutter 24, the roller 26, and the camera 28 are configured to, when the support member 20 is rotated in a predetermined rotation direction, sequentially pass through the same space in this order. Specifically, the cutter 24, the roller 26, and the camera 28 are, for example, arranged on the second surface 20b in such a manner as to pass through one space that is present below the support member 20 in this order, when the support member 20 is rotated in the direction of an arrow illustrated in FIG. 10.

An output apparatus 32 is connected to the camera 28 disposed on the support member 20. The output apparatus 32 is, for example, a display or the like, and outputs the image captured by the camera 28, in a visually recognizable manner for an operator. Note that the camera 28 may either be a visible camera having sensitivity for light in a visible range or an infrared camera having sensitivity for light in an infrared range, on condition that the camera 28 can capture an image of a portion near a boundary between the substrate 11 and the protective member 51. Further, the camera 28 may be connected to the output apparatus 32 either in a wired or wireless manner. Specifically, the image captured by the camera 28 may be output to the output apparatus 32 in a wireless manner.

A support table 36 is disposed below the cutting unit 18. The support table 36 is configured to have a substantially disk-shape and includes a substantially circular face side 36a and a substantially circular reverse side 36b. The face side 36a of the support table 36 has a diameter (width) slightly larger than that of the substrate 11 to come into contact with the entire reverse side 11b of the substrate 11 and to hold the substrate 11. For example, the diameter (width) of the face side 36a is larger than the diameter (width) of the substrate 11 by 50 mm.

The support table 36 has a groove 36c that has an upper end open on the face side 36a of the support table 36 and that is configured to have an annular shape extending along the circumference direction of the support table 36. The groove 36c serves as a clearance groove for avoiding a blade constituting the cutter 24 and preventing interference between the cutter 24 and the support table 36, in the removing step S3 described later.

As illustrated in FIG. 9, in the reference image acquiring step S2, first, the substrate 11 on which the protective member 51 is formed is disposed on the face side 36a of the support table 36. Next, the rotary drive source causes the spindle 22 to make one rotation about the rotational axis 30. As a result, the camera 28 moves along the circumference of a circle having substantially the same diameter as the substrate 11.

While moving along the circumference in association with the rotation of the spindle 22, the camera 28 images the protective member 51 and the substrate 11 that are supported by the support table 36 disposed below. Specifically, the camera 28 captures an image of a portion where the protective member 51 and the substrate 11 come into contact with each other, along the circumference direction of the protective member 51. As described above, the camera 28 moves along the circumference of a circle having substantially the same diameter as the substrate 11. Hence, as a result of this imaging, an image of a region including a portion corresponding to the peripheral edge of the substrate 11 is obtained.

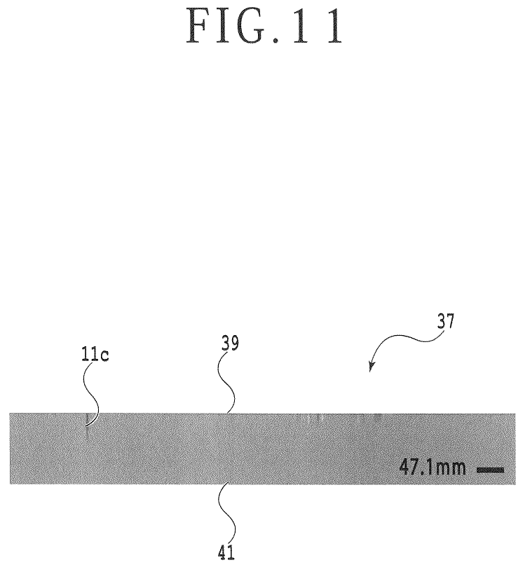

FIG. 11 illustrates an example of an image acquired in the reference image acquiring step S2. The image denoted by 37 and illustrated in FIG. 11 is, for example, obtained by the camera 28 focusing on a portion near the boundary between the substrate 11 and the protective member 51 and capturing an image along the circumference direction of the cover film 49. The image 37 illustrated in FIG. 11 includes a region including a first end portion 39 corresponding to the peripheral edge of the substrate 11 and a second end portion 41 that is on the central side by a predetermined distance from the first end portion 39. The image 37 subsequently serves as the reference image for determining presence or absence of an abnormality in the quality of the protective member 21. Note that the image 37 also includes the notch 11c of the substrate 11.

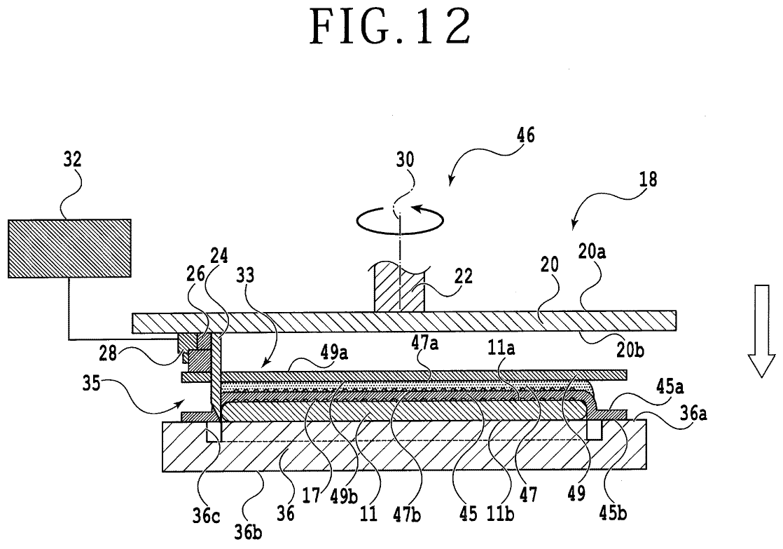

After the reference image acquiring step S2, the removing step S3 is carried out. FIG. 12 is a cross sectional view illustrating the substrate 11, the protective member 51, and other members at the time when the removing step S3 is carried out. In the removing step S3, the Z-axis moving mechanism lowers the cutting unit 18 along the Z-axis. As a result, the cutter 24 cuts into a portion of the protective member 51 that corresponds to the peripheral edge of the substrate 11. Thereafter, the spindle 22 is caused to make one rotation about the rotational axis 30, so that the cutter 24 makes one revolution along the peripheral edge of the substrate 11 in a state in which the cutter 24 has cut into the protective member 51.

As a result, the protective member 51 is separated into a main body portion 33 on an inner side than the peripheral edge of the substrate 11 and a surplus portion 35 extending beyond the peripheral edge of the substrate 11. Subsequently, the surplus portion 35 is removed from the substrate 11. The main body portion 33 corresponds to the protective member 21 illustrated in FIG. 3.

After the removing step S3 is started, the pressing step S4 and the determination target image acquiring step S5 are sequentially carried out. In the pressing step S4, the roller 26 provided on the support member 20 presses the peripheral edge of the main body portion 33 of the protective member 51. Further, in the determination target image acquiring step S5, the peripheral edge of the main body portion 33 of the protective member 51 is imaged by the camera 28.

As described above, in the present embodiment, the cutter 24, the roller 26, and the camera 28 are so arranged as to pass through the same space in this order when the support member 20 is rotated in a predetermined rotation direction. Further, before the removing step S3 is started, the height of each of the cutter 24, the roller 26, and the camera 28 is adjusted such that, when the cutter 24 cuts the protective member 51, the roller 26 comes into contact with the protective member 51 and the camera 28 focuses on the portion near the boundary between the substrate 11 and the protective member 51.

Hence, after the cutter 24 has cut into the protective member 51, pressing of the peripheral edge of the main body portion 33 by the roller 26 and imaging of the portion near the boundary between the substrate 11 and the protective member 51 by the camera 28 are sequentially performed. That is, in the present embodiment, the pressing step S4 and the determination target image acquiring step S5 are carried out in parallel while the removing step S3 is being carried out.

Yet, the pressing step S4 and the determination target image acquiring step S5 may be carried out after the removing step S3 is ended. Further, in the present embodiment, the pressing step S4 is started prior to the determination target image acquiring step S5, but the determination target image acquiring step S5 may be started prior to the pressing step S4.

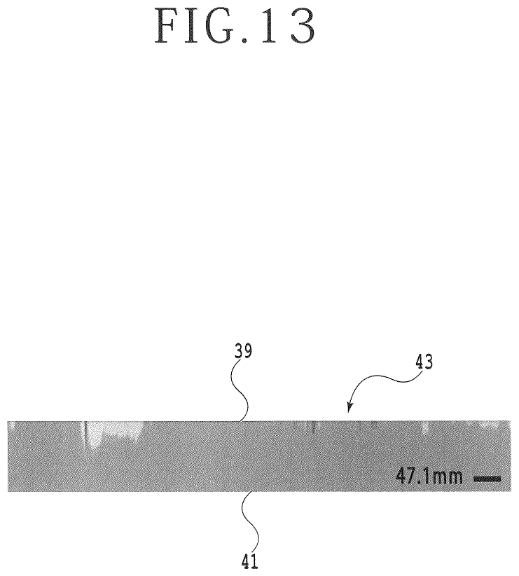

FIG. 13 illustrates an example of an image acquired in the determination target image acquiring step S5. A region appearing in an image 43 illustrated in FIG. 13 and acquired in the determination target image acquiring step S5 is the same region as the region imaged at the time of capturing the image 37 that is illustrated in FIG. 11 and that serves as the reference image. The image 43 acquired in the determination target image acquiring step S5 serves as the determination target image for determining the presence or absence of an abnormality in the quality of the protective member 21.

Next, in the determining step S6, the image 37 acquired in the reference image acquiring step S2 and the image 43 acquired in the determination target image acquiring step S5 are compared to determine whether there is an abnormality in the main body portion 33 of the protective member 51.

Specifically, for example, taking a difference between luminance of each of a plurality of pixels constituting the image 37 acquired in the reference image acquiring step S2 and luminance of each of a plurality of pixels constituting the image 43 acquired in the determination target image acquiring step S5, an image (first difference image) indicating presence or absence of an abnormality in the quality of the protective member 21 is formed. That is, taking the difference in luminance of pixels that are in a correspondence relation (pixels located at the same positions) in the image 37 and the image 43, new pixels constituting the image (first difference image) are formed.

Thereafter, by applying binarization processing to the image (first difference image), a difference image (second difference image) that includes a first region including pixels of low luminance and a second region including pixels of luminance higher than that of pixels constituting the first region is formed. Note that, in the present embodiment, the second difference image is obtained by application of binarization processing to the first difference image, but the binarization processing may be applied to each of the image 37 and the image 43, and thereafter the difference in luminance of the respective pixels can be taken to form a binarized difference image.

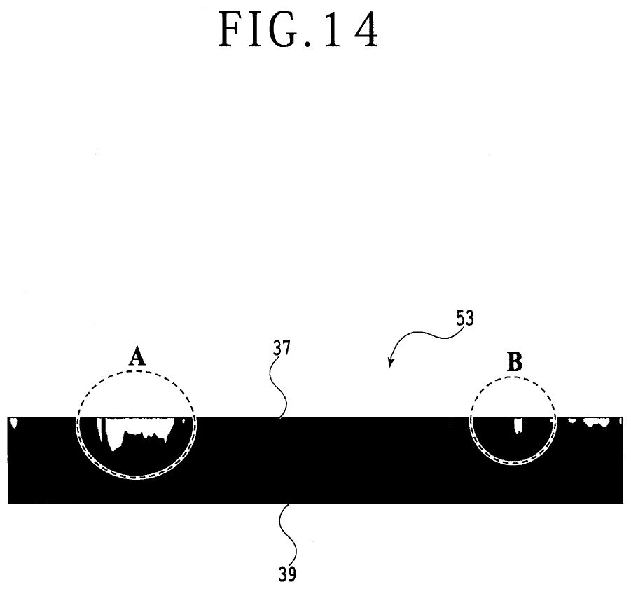

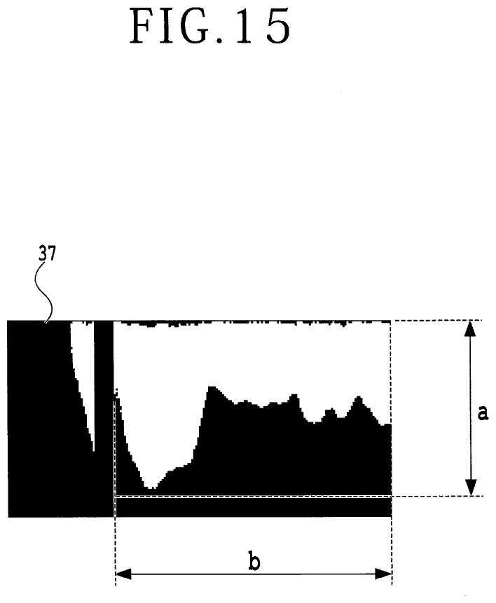

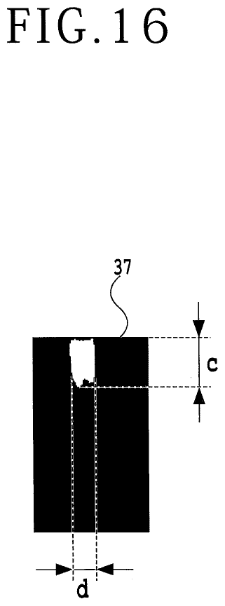

FIG. 14 illustrates a difference image (second difference image) 53 that is obtained from the image 37 acquired in the reference image acquiring step S2 and the image 43 acquired in the determination target image acquiring step S5. Further, FIG. 15 is an enlarged view of a portion indicated by sign A in the difference image 53 illustrated in FIG. 14, while FIG. 16 is an enlarge view of a portion indicated by sign B in the difference image 53 illustrated in FIG. 14. In the difference image 53 illustrated in FIG. 14, FIG. 15, and FIG. 16, the black portion is the first region, while the white portion is the second region. The second region is a portion where the luminance of the image 43 has changed with respect to the image 37 and which corresponds to the peripheral edge of the protective member 21 where an abnormality is assumed to have occurred. Here, an abnormality refers to peeling-off of the protective member 21 from the substrate 11.

In the determining step S6, the size of the second region is calculated. Specifically, an area of the second region, a length of the second region (which is a distance in a direction toward the second end portion 41 from the first end portion 39; for example, a distance “a” depicted in FIG. 15 and a distance “c” depicted in FIG. 16), or a width of the second region (which is a distance in a direction perpendicular to the direction toward the second end portion 41 from the first end portion 39; for example, a distance “b” depicted in FIG. 15 and a distance “d” depicted in FIG. 16).

In a case where the size of the second region exceeds a predetermined first threshold, the operator determines that there is an “abnormality” in the main body portion 33 of the protective member 51. For example, in a case where an area of portion “A” is 7 mm² while a threshold for the area is set to 3 mm², the area of portion “A” exceeds the threshold, so that the operator determines that there is an “abnormality.” Note that the determination of the presence or absence of an abnormality and setting of the threshold may be performed by a computer instead of an operator. For example, the presence or absence of an abnormality may be determined by the cutting apparatus 46 including a controller that has a processing apparatus and a storage apparatus and the processing apparatus referring to the first threshold stored in the storage apparatus.

When the operator determines in the determining step S6 that there is an “abnormality,” the peeling-off step S7 of peeling off the protective member 21 from the substrate 11 is carried out. For example, the protective member 21 can be peeled off from the substrate 11 by the resin film 23 being heated by a heat sealer and being softened. Further, after a new protective member 21 has been formed on the substrate 11 by the protective member forming step S1 being performed again, the reference image acquiring step S2, the removing step S3, the pressing step S4, the determination target image acquiring step S5, and the determining step S6 are sequentially carried out. Yet, the method of peeling off the protective member 21 from the substrate 11 in the peeling-off step S7 is not limited to the method described above.

When the operator determines in the determining step S6 that there is “no abnormality,” on the other hand, the manufacturing method of a substrate with a protective member including the series of steps described above is ended.

As described above, in the manufacturing method of a substrate with a protective member according to the first embodiment, the presence or absence of an abnormality in the quality of the peripheral edge of the main body portion 33 is determined by observation of the peripheral edge of the main body portion 33 of the protective member 21. Thus, the presence or absence of an abnormality in the quality of the protective member 21 formed on the substrate 11 can be determined.

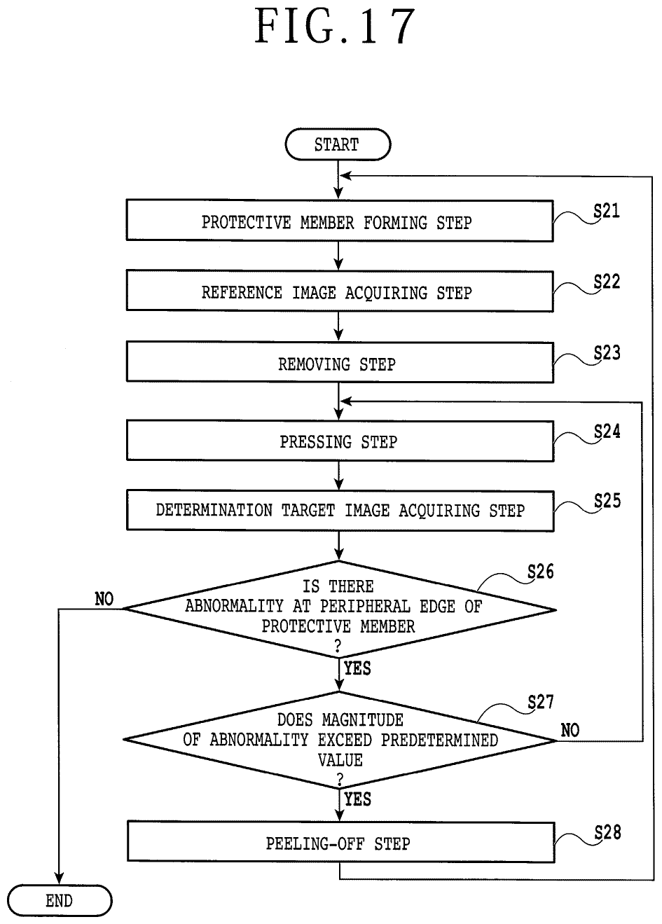

FIG. 17 is a flowchart illustrating a manufacturing method of a substrate with a protective member according to a second embodiment of the present invention. As illustrated in FIG. 17, the manufacturing method of a substrate with a protective member according to a second embodiment includes a protective member forming step S21, a reference image acquiring step S22, a removing step S23, a pressing step S24, a determination target image acquiring step S25, a first determining step S26, a second determining step 27, and a peeling-off step S28.

The protective member forming step S21, the reference image acquiring step S22, the removing step S23, the pressing step S24, the determination target image acquiring step S25, and the first determining step S26 are each identical to the protective member forming step S1, the reference image acquiring step S2, the removing step S3, the pressing step S4, the determination target image acquiring step S5, and the determining step S6 in the manufacturing method of a substrate with a protective member according to the first embodiment.

That is, the manufacturing method of a substrate with a protective member according to the second embodiment is different from the manufacturing method of a substrate with a protective member according to the first embodiment in including the second determining step S27 and the peeling-off step S28 that is carried out in reference to the result of the second determining step S27. In the second determining step S27, whether the magnitude of the abnormality detected in the first determining step S26 exceeds a predetermined second threshold is determined.

When the magnitude of the abnormality does not exceed the predetermined second threshold, the pressing step S24 is carried out. For example, when the area of the portion where the protective member 21 is peeled off does not exceed the second threshold, the peripheral edge of the main body portion 33 is pressed by the roller 26 again, so that the protective member 21 is adhered to the substrate 11 and the portion where the protective member 21 is peeled off is repaired.

When the magnitude of the abnormality detected in the first determining step S26 exceeds the predetermined second threshold in the second determining step S27, on the other hand, the peeling-off step S28 of peeling off the protective member 21 from the substrate 11 is carried out. When a new protective member 21 is formed on the substrate 11 after the protective member forming step S21 has been performed again, the reference image acquiring step S22, the removing step S23, the pressing step S24, the determination target image acquiring step S25, and the first determining step S26 are sequentially carried out.

As described above, also in the manufacturing method of a substrate with a protective member according to the second embodiment, the presence or absence of an abnormality in the quality of the peripheral edge of the main body portion 33 is determined by observation of the peripheral edge of the main body portion 33. Thus, the presence or absence of an abnormality in the quality of the protective member 21 formed on the substrate 11 can be determined.

Note that the methods and the apparatuses illustrated in the embodiments can variously be altered. For example, while cutting and imaging of the protective member 21 are performed with the cutting unit 18 being rotated, in the reference image acquiring step S2, the removing step S3, and the determination target image acquiring step S5 according to the first embodiment, the support table 36 supporting the substrate 11 may instead be rotated. That is, the support table 36 may be connected to the rotary drive source and rotated about the rotational axis by power from this rotary drive source.

Further, the resin layer 25 may be configured by a cured product of ultraviolet curable resin. In this case, instead of being irradiated by ultraviolet rays, the liquid resin 31 cures by being heated by a heating apparatus such as a heater, in the cover film disposing step S13.

Further, the reference image acquiring step S2 and the reference image acquiring step S22 may each be omitted. That is, in each of the determining step S5 and the first determining step S26, an abnormality at the peripheral edge of the protective member 21 may be determined with use of only the determination target image without the reference image being used.

In this case, the operator recognizes in advance such characteristics as the luminance or shape of the portion where an abnormality is found in the image. Alternatively, when a computer is to be used for determining the presence or absence of an abnormality, the storage apparatus stores such characteristics beforehand. The operator or the computer determines whether such characteristics appear in the determination target image. Yet, when marks or the like are present on the peripheral edge of the protective member 21, using the abovementioned reference image can exclude the influence of the marks or the like and is more likely to increase the accuracy of determination.

Further, in the embodiments described above, while the image captured by the camera 28 is used for determining the presence or absence of an abnormality, a fiber sensor or a color sensor may be used in place of the camera 28. The fiber sensor includes a light projecting section that emits light and a light receiving section into which light that has been emitted from the light projecting section and has been reflected by a measurement target enters. The light projecting section includes a fluorescent light, a light emitting diode (LED), or the like. Further the light receiving section includes a charge coupled device (CCD) image sensor, a complementary metal oxide semiconductor (CMOS) image sensor, or the like.

For example, when light enters the portion where the protective member 21 is peeled off, the light scatters (diffusely reflects) by an air layer, so that the amount of reflection of light by the substrate 11 decreases, and the intensity of light entering the light receiving section becomes smaller than that in the portion where the protective member 21 is not peeled off. Accordingly, the presence or absence of peeling-off of the protective member 21 at the peripheral edge thereof is determined by measurement of the intensity of light entering the light receiving section.

Further, similarly to the fiber sensor, the color sensor includes a light projecting section that emits light and a light receiving section into which light that has been emitted from the light projecting section and that has been reflected by a measurement target enters. The color sensor can detect the intensity of each of the components of light of blue, red, and green. When light enters the portion where the protective member 21 is peeled off, light scatters (diffusely reflects) by an air layer, so that the amount of reflection of light by the substrate 11 decreases, and the light entering the light receiving section becomes whiter than that in the portion where the protective member 21 is not peeled off. Accordingly, the presence or absence of peeling-off of the protective member 21 at the peripheral edge thereof is determined by measurement of the intensity of each component of light entering the light receiving section.

Besides, structures, methods, and other relevant matters according to the embodiments and modifications can be implemented with changes applied thereto within the scope not departing from the object of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A manufacturing method of a substrate with a protective member in which a protective member of a size corresponding to a substrate is provided on one side of the substrate, the method comprising:
a protective member forming step of forming a protective member having a width greater than a width of the substrate, on the one side of the substrate;
a removing step of, after the protective member forming step, causing a cutter to cut into the protective member along a peripheral edge of the substrate and separating the protective member into a surplus portion extending beyond the peripheral edge of the substrate and a main body portion on an inner side than the peripheral edge of the substrate, to remove the surplus region; and
a determining step of, after the removing step, observing a peripheral edge of the main body portion and determining presence or absence of occurrence of an abnormality at the peripheral edge of the main body portion.

2. The manufacturing method of a substrate with a protective member according to claim 1, further comprising:
a reference image acquiring step of, after the protective member forming step but before the removing step, imaging the protective member at a portion corresponding to the peripheral edge of the substrate and acquiring a reference image that serves as reference for determination in the determining step; and
a determination target image acquiring step of, after the removing step but before the determining step, imaging the peripheral edge of the main body portion of the protective member and acquiring a determination target image that would be used for determination in the determining step, wherein,
in the determining step, the reference image and the determination target image are compared.

3. The manufacturing method of a substrate with a protective member according to claim 2, wherein,
in the determining step, a difference between luminance of each of a plurality of pixels constituting the determination target image and luminance of each of a plurality of pixels constituting the reference image is taken to form a difference image that includes a first region including pixels of low luminance and a second region including pixels of higher luminance than the pixels constituting the first region, and,
when a size of the second region indicated in the difference image exceeds a threshold, an abnormality is determined to have occurred.

4. The manufacturing method of a substrate with a protective member according to claim 1, further comprising:
a pressing step of, after the removing step but before the determining step, pressing the peripheral edge of the main body portion by a roller.

5. The manufacturing method of a substrate with a protective member according to claim 2, further comprising:
a pressing step of, after the removing step but before the determining step, pressing the peripheral edge of the main body portion by a roller.

6. The manufacturing method of a substrate with a protective member according to claim 3, further comprising:
a pressing step of, after the removing step but before the determining step, pressing the peripheral edge of the main body portion by a roller.

7. The manufacturing method of a substrate with a protective member according to claim 1, further comprising:
a pressing step of, after the determining step, pressing the peripheral edge of the main body portion by a roller.

8. The manufacturing method of a substrate with a protective member according to claim 2, further comprising:
a pressing step of, after the determining step, pressing the peripheral edge of the main body portion by a roller.

9. The manufacturing method of a substrate with a protective member according to claim 3, further comprising:
a pressing step of, after the determining step, pressing the peripheral edge of the main body portion by a roller.

10. The manufacturing method of a substrate with a protective member according to claim 1, further comprising:
a peeling-off step of peeling off the main body portion from the substrate when, in the determining step, an abnormality is determined to have occurred, wherein,
after the peeling-off step, the protective member forming step, the removing step, and the determining step that use the protective member newly formed are carried out.

11. The manufacturing method of a substrate with a protective member according to claim 2, further comprising:
a peeling-off step of peeling off the main body portion from the substrate when, in the determining step, an abnormality is determined to have occurred, wherein,
after the peeling-off step, the protective member forming step, the removing step, and the determining step that use the protective member newly formed are carried out.

12. The manufacturing method of a substrate with a protective member according to claim 3, further comprising:
a peeling-off step of peeling off the main body portion from the substrate when, in the determining step, an abnormality is determined to have occurred, wherein,
after the peeling-off step, the protective member forming step, the removing step, and the determining step that use the protective member newly formed are carried out.

13. The manufacturing method of a substrate with a protective member according to claim 1, wherein
the protective member forming step includes
a resin film adhering step of causing one side of a resin film having a width greater than the width of the substrate to adhere to the one side of the substrate,
a liquid resin supplying step of supplying liquid resin to a side of the resin film opposite to the one side thereof, and
a cover film disposing step of disposing a cover film having a width greater than the width of the substrate on the resin and curing the resin.

14. The manufacturing method of a substrate with a protective member according to claim 2, wherein
the protective member forming step includes
a resin film adhering step of causing one side of a resin film having a width greater than the width of the substrate to adhere to the one side of the substrate,
a liquid resin supplying step of supplying liquid resin to a side of the resin film opposite to the one side thereof, and
a cover film disposing step of disposing a cover film having a width greater than the width of the substrate on the resin and curing the resin.

15. The manufacturing method of a substrate with a protective member according to claim 3, wherein
the protective member forming step includes
a resin film adhering step of causing one side of a resin film having a width greater than the width of the substrate to adhere to the one side of the substrate,
a liquid resin supplying step of supplying liquid resin to a side of the resin film opposite to the one side thereof, and
a cover film disposing step of disposing a cover film having a width greater than the width of the substrate on the resin and curing the resin.
